(19) United States
(12) Patent Application Publication
(10) Pub. No.: US 2006/0145170 A1
(43) Pub. Date: Jul. 6, 2006

(54) Nitride based semiconductor light emitting device

(75) Inventor: Dong Hyun Cho, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/319,973

(22) Filed: Dec. 28, 2005

(30) Foreign Application Priority Data
Jan. 3, 2005 (KR) 10-2005-266

(51) Int. Cl. H01L 33/00

(52) U.S. Cl. 257/95; 257/98

(57) ABSTRACT

The present invention provides a nitride-based semiconductor light emitting device basically comprising a first conductivity type nitride semiconductor layer, active layer and second conductivity type nitride semiconductor layer, which are sequentially formed on a light-permeable substrate in this order. The light emitting device further comprises an insulating light-scattering layer formed on at least one surface thereof. The insulating light-scattering layer is made of an insulating material having a light permeability of more than 50% and is formed at an outer surface thereof with a roughened pattern for the scattering of light.

### RELATED APPLICATIONS

The present application is based on, and claims priority from, Korean Application Number 2005-0000226, filed Jan. 3, 2005, the disclosure of which is incorporated by reference herein in its entirety.

### BACKGROUND OF THE INVENTION

1. Field of the Invention

The present invention relates to nitride-based semiconductor light emitting devices, and more particularly to nitride-based semiconductor light emitting devices and flip-chip type nitride-based semiconductor light emitting devices with improved light extraction efficiency.

2. Description of the Related Art

Nitride-based semiconductor light emitting devices are high-power optical devices capable of generating light in a wide wavelength band including short wavelength light of blue or green light, and are in the spotlight in the related technical field. Such nitride-based semiconductor light emitting devices comprise semiconductor single crystals with the formula AlₓIn_{y}Ga_{(1-x-y)}N (where 0≦x≦1, 0≦y≦1, 0≦x+y≦1).

In general, light efficiency of the nitride-based semiconductor light emitting devices is determined by internal quantum efficiency and light extraction efficiency (frequently referred to as external quantum efficiency). Here, the light extraction efficiency is determined by optical factors of a light emitting device, i.e. refraction index of respective semiconductor structures and/or interfacial flatness, etc.

In relation with the light extraction efficiency, the nitride-based semiconductor light emitting devices have a basic restriction. That is, semiconductor layers of the semiconductor light emitting devices have higher refraction index as compared to the outside air or substrates, and consequently cause only a small critical angle that determines the range of an incidence angle of light to be emitted from the semiconductor light emitting devices. As a result, much of light, coming from active layers, shows total internal reflection, thereby being propagated in an undesired direction or being completely reflected and dissipated, resulting in only low light extraction efficiency.

More specifically, in nitride-based semiconductor light emitting devices where refraction index of a GaN layer is 2.4, light coming from active layers causes total internal reflection if its incidence angle is larger than 23.6° that is a critical angle at an GaN/air interface, thereby being propagated laterally to be dissipated or being propagated in an undesired direction, resulting in low light extraction efficiency of only 6%. Similarly, since refraction index. of a sapphire substrate is 1.78, only low light extraction efficiency is achieved at an interface of the sapphire substrate and the outside air.

As a solution of the low light extraction efficiency problem, Japanese Patent Publication No. 2002-368263, published on Dec. 20, 2002 by the applicant of Toyota Gosei Co. Ltd., discloses a flip-chip type nitride-based light emitting device in which a substrate has a rough lower surface. FIGS. 1a and 1b illustrate the flip-chip type nitride-based light emitting device of the referenced Japanese Patent Publication.

Referring to FIG. 1a, the disclosed nitride-based semiconductor light emitting device 10 comprises a first conductivity type nitride semiconductor layer 14, an active layer 15 and a second conductivity type nitride semiconductor layer 16, which are sequentially formed on a sapphire substrate 11 in this order. In addition, a buffer layer 12 is formed at an upper surface of the sapphire substrate 11 to improve crystalinity of the nitride semiconductor layers. The nitride semiconductor light emitting device 10 further comprises first and second electrodes 19a and 19b connected to the first and second conductivity type nitride semiconductor layers 14 and 16, respectively. Here, a lower surface 11a of the sapphire substrate 11 is roughened via an etching process to define a light-scattering surface.

Referring to FIG. 1b, the nitride-based semiconductor light emitting device 10 is mounted on a package substrate 21 having first and second conductor lines 22a and 22b, and the first and second electrodes 19a and 19b of the nitride-based semiconductor light emitting device 10 are connected to the first and second conductor lines 22a and 22b, respectively, by means of connecting means S, such as solder, to thereby manufacture a flip-chip type nitride-based semiconductor light emitting device 20. In this case, the lower surface 11a of the sapphire substrate 11, defining a light-scattering surface, also serves as a light emitting surface. In the flip-chip type nitride-based semiconductor light emitting device 20, light coming from the active layer 15 proceeds to the light emitting surface 11a as it is reflected at the bottom of the device 20 as designated by the arrow b, or directly proceeds to the light emitting surface 11a as designated by the arrow a. The light, arriving at the light emitting surface 11a, is partially scattered at the lower surface 11a of the sapphire substrate 11 or is effectively emitted to the outside due to a large critical angle provided by a finely roughened pattern provided at the lower surface 11a.

However, due to the fact that substrates, usually employed for the growth of nitride, are sapphire substrates having a high hardness, the above described prior art has a problem that it is difficult to provide the sapphire substrates with a rough surface, i.e. finely roughened pattern, and to accurately control a patterning process to achieve a desired roughened pattern.

Moreover, since the patterning process is selected from among mechanical/chemical processes using abrasives and other chemical etching processes, which exhibit many troubles in relation with nitride-based semiconductor applications, the patterning process must be applied only to sapphire substrates. As a result, the application range of the patterning technique is extremely restricted only to flip-chip type structures.

### SUMMARY OF THE INVENTION

Therefore, the present invention has been made in view of the above problems, and it is an object of the present invention to provide a nitride-based semiconductor light emitting device and flip-chip type light emitting device, in which a light-scattering layer, that is made of a light-permeable insulating material and has a roughened pattern, is formed on at least one surface of the light emitting device.

In accordance with one aspect of the present invention, the above and other objects can be accomplished by the provision of a nitride-based semiconductor light emitting device comprising a first conductivity type nitride semiconductor layer, active layer and second conductivity type nitride semiconductor layer, which are sequentially formed on a light-permeable substrate in this order, further comprising: an insulating light-scattering layer formed on at least one surface of the nitride-based semiconductor light emitting device, the light-scattering layer being made of an insulating material having a light permeability of more than 50% and being formed at an outer surface thereof with a roughened pattern for the scattering of light.

Preferably, the insulating light-scattering layer may have a light permeability of more than 70%, and may be made of a polymer material, such as epoxy based resin, silicone based resin or PMMA. In this case, the insulating light-scattering layer may further comprise fluorescent material for exciting light. Alternatively, the insulating light-scattering layer also may be made of a material selected from the group consisting of GaN, AlN, InN, SiNx, SiC, diamond, Al₂O₃, SiO₂, SnO₂, TiO₂, ZrO₂, MgO, InOₓ and CuOₓ.

Preferably, the insulating light-scattering layer may have a pattern pitch within a range of approximately 0.001 to 50 μm, and may be a regular pattern having a predetermined shape and pitch.

In a first exemplary embodiment of the present invention, the insulating light-scattering layer may be formed on at least a lower surface of the light-permeable substrate. Alternatively, the insulating light-scattering layer may be made of a particle layer having a particle size of 50 μm. Preferably, the insulating light-scattering layer may be made of a material having a refraction index higher than that of the light-permeable substrate in order to enhance scattering effect.

In a second exemplary embodiment of the present invention, the insulating light-scattering layer may be formed at an upper surface of the nitride-based semiconductor light emitting device opposite to the light-permeable substrate. In this case, the insulating light-scattering layer may extend from the upper surface of the nitride-based semiconductor light emitting device to at least a part of a sidewall of the light emitting device. Preferably, the insulating light-scattering layer may be made of a material having a refraction index higher than that of the first and second conductivity type nitride semiconductor layers in order to enhance scattering effect.

In a third exemplary embodiment of the present invention, the nitride-based semiconductor light emitting device may further comprise a reflective metal layer formed on at least one surface of the nitride-based semiconductor light emitting device except for a light emitting surface. Here, the reflective metal layer may be formed on the insulating light-scattering layer. In the present exemplary embodiment, preferably, the reflective metal layer may have a reflectivity of more than 90%, and may be made of at least one metal selected from the group consisting of Ag, Al, Rh, Ru, Pt, Au, Cu, Pd, Cr, Ni, Co, Ti, In and Mo or alloys thereof. Here, the metal or alloy may be formed into at least one layer.

In a fourth exemplary embodiment of the present invention, the light-permeable substrate may have an inclined surface along at least a part of a lateral end of a lower surface thereof, and the insulating light-scattering layer may be formed on at least the lower surface of the light-permeable substrate and the inclined surface. Preferably, the insulating light-scattering layer may be made of a material having a refraction index higher than that of the light-permeable substrate in order to enhance scattering effect.

In accordance with another aspect of the present invention, the above and other objects can be accomplished by the provision of a flip-chip type nitride-based semiconductor light emitting device comprising: a nitride-based semiconductor light emitting device having a first conductivity type nitride semiconductor layer, active layer and second conductivity type nitride semiconductor layer, which are sequentially formed on a light-permeable substrate in this order, and first and second electrodes connected to the first and second conductivity type nitride semiconductor layers, respectively; a package substrate having first and second conductor lines to be connected to the first and second electrodes, respectively; and an insulating light-scattering layer formed on at least a lower surface of the light-permeable substrate, the insulating light-scattering layer being made of an insulating material having a light permeability of more than 50% and being formed at an outer surface thereof with a roughened pattern for the scattering of light.

Differently from the prior art that a roughened pattern is directly formed at a sapphire substrate having a high hardness or at other nitride semiconductor regions, the present invention suggests that a light-permeable insulating material is deposited on at least one surface of a light emitting device to form an insulating layer, and a roughened pattern is formed at the insulating layer, thereby achieving a light-scattering layer to improve light extraction efficiency of the light emitting device. Further, the insulating light-scattering layer acts as a protective film, so can be freely formed at the overall surface of the device except for electrode formation locations. Therefore, the insulating light-scattering layer of the present invention is advantageously applicable to other certain structures where the upper surface of a nitride layer serves as a light emitting surface, in addition to flip-chip structures.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a and 1b are side sectional views, respectively, illustrating a nitride-based semiconductor light emitting device and flip-chip type nitride-based semiconductor light emitting device of the prior art;

FIGS. 2a and 2b are side sectional views, respectively, illustrating a nitride-based semiconductor light emitting device and flip-chip type nitride-based semiconductor light emitting device in accordance with a first exemplary embodiment of the present invention;

FIG. 2c is a detailed view of part of the flip-chip type nitride-based semiconductor light emitting device of FIG. 2b;

FIG. 3 is a side sectional view of a nitride-based semiconductor light emitting device in accordance with a second exemplary embodiment of the present invention;

FIG. 4 is a side sectional view of a nitride-based semiconductor light emitting device in accordance with a third exemplary embodiment of the present invention; and

FIG. 5 is a side sectional view of a nitride-based semiconductor light emitting device in accordance with a fourth exemplary embodiment of the present invention.

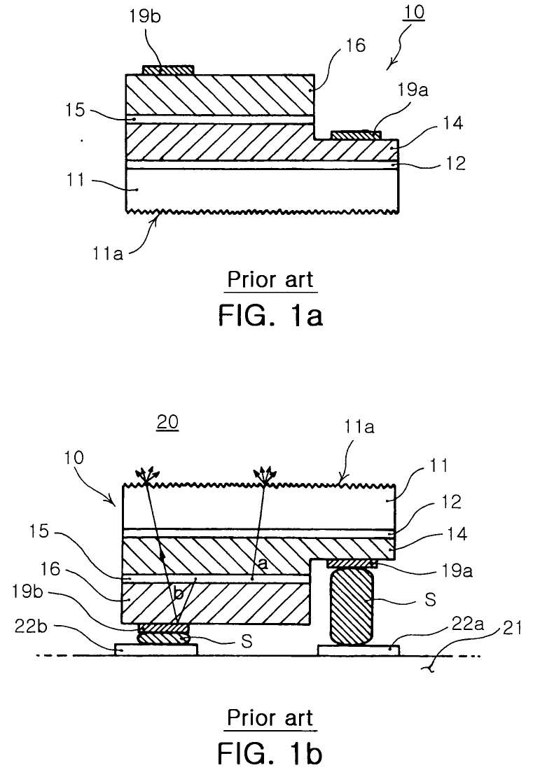

### DESCRIPTION OF THE PREFERRED EMBODIMENTS

Now, preferred exemplary embodiments of the present invention will be explained in more detail with reference to the accompanying drawings.

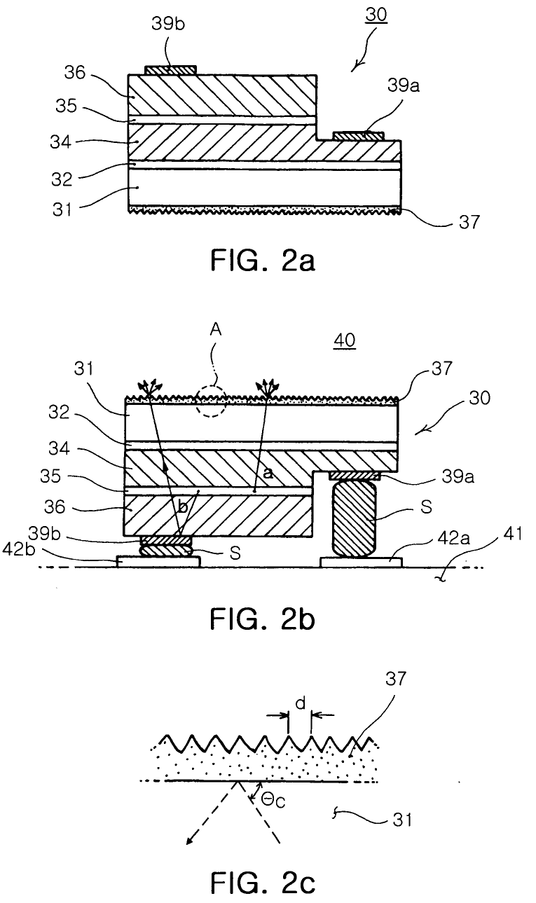

FIG. 2a is a side sectional view of a nitride-based semiconductor light emitting device in accordance with a first exemplary embodiment of the present invention. It can be understood that the nitride-based semiconductor light emitting device shown in FIG. 2a is employed in a flip-chip type light emitting device as shown in FIG. 2b.

Referring to FIG. 2a, the nitride-based semiconductor light emitting device 30, in accordance with the first exemplary embodiment of the present invention, comprises a first conductivity type nitride semiconductor layer 34, an active layer 35 and a second conductivity type nitride semiconductor layer 36, which are sequentially formed on a sapphire substrate 31 in this order. In addition, a buffer layer 32 is formed at an upper surface of the sapphire substrate 31 to alleviate a lattice mismatch phenomenon. The nitride-based semiconductor light emitting device 30 further comprises first and second electrodes 39a and 39b connected to the first and second conductivity type nitride semiconductor layers 34 and 36, respectively. The first conductivity type nitride semiconductor layer 34 may be a multilayer structure of n-type AlGaN/n-type GaN, and the second conductivity type nitride semiconductor layer 36 may be a multilayer structure of p-type AlGaN/p-type GaN. The active layer 35 may have a multiple quantum well structure expressed by AlₓIn_{y}Ga_{1-x-y}N/In_{y}Ga_{1-y}N, where 0≦x≦1 and 0≦y≦1.

In the present exemplary embodiment, an insulating light-scattering layer 37 is formed on a lower surface of the sapphire substrate 31. The insulating light-scattering layer 37 is made of an insulating material having a light permeability of more than 50%, preferably more than 70%. The insulating light-scattering layer 37 is provided at an outer surface thereof with a finely roughened pattern effective to scatter light. The finely roughened pattern is easily obtainable via a photolithography process or etching process using a metallic mask. Such roughened pattern is variable in size and pitch in relation with light-emitting wavelengths, and is able to be regularly or irregularly formed. Provided that the insulating light-scattering layer 37 emits short-wavelength light, i.e. blue or green light, the roughened pattern preferably has a pitch of 0.001 to 50 μm, and may have a regular pattern of a predetermined size and pitch.

The insulating material, constituting the insulating light-scattering layer 37, is selected from among insulating materials showing high adherence relative to sapphire substrates as well as sufficient light permeability. For example, the insulating material may be a polymer-based # material or material selected from the group consisting of GaN, AlN, InN, SiNx, SiC, diamond, Al₂O₃, SiO₂, SnO₂, TiO₂, ZrO₂, MgO, InOₓ and CuOₓ. In the former case, it is preferable to select a polymer material showing a heat resistance at a temperature of approximately 150° C. or more in order to prevent deformation of the insulating light-scattering layer due to heat generated upon operation of the light emitting device. Examples of the polymer material include epoxy resin, silicone resin and poly(methyl methacrylate (PMMA) resin.

Most preferably, SiO₂ or SiNx for use in conventional semiconductor processes is selected to constitute the insulating light-scattering layer 37. Such SiO₂ or SiNₓ is advantageous to facilitate a deposition process and patterning process in relation with conventional semiconductor processes.

Also, the polymer material such as epoxy resin, silicone resin and PMMA resin may include a fluorescent material for exciting light to convert light wavelength emitted from the active layer 35 into other wavelength. The fluorescent material may include at least one selected from a group consisting of Garnet-based (A3B5O12: CeD, A=Y, Tb, Lu, La, Sm, Gd, Se; B═Al, Ga, In; D=Tb, Eu) Silicate-based (Sr Ba (Ca, Mg, Zn, Cd))x(Si(P, B, Ge, Al))yOz:Eu(F, Cl, Br, I, P, S, N, rare earths), nitride-based ((SrSiOAl)N:Eu, rare earths), and Sulfur-based (Srx (Ca, Ga, Zn)y)S:Eu, Cu, Au, Al, rare earths), where 0≦y≦1, 0≦y≦1, and 0≦z≦1ₒ

The insulating light-scattering layer 37 is advantageously made of a material having a refraction index higher than that of the sapphire substrate 31 in order to enhance light-scattering efficiency. For example, the insulating light-scattering layer 37 made of diamond (refraction index of 2.42) allows a refraction index higher than that (1.78) of the sapphire substrate 31. As shown in FIG. 2c, the passing of the light-scattering layer leads to big critical angle (θ_{c}), but it increases light extraction efficiency through scattering effect. Most preferably, a particle layer having a refraction index higher than that of a substrate or a semiconductor layer may be employed. In case of using fluorescent material for exciting light for the purpose of white-light emission, the particle layer may be made of the fluorescent material.

Therefore, in the nitride-based semiconductor light emitting device of the present exemplary embodiment, a reduced amount of light shows total internal reflection, that is caused when an incidence angle of the light is larger than a critical angle. This consequently increases the amount of light emitted, achieving a high improvement of light extraction efficiency.

The above described nitride-based semiconductor light emitting device is employed in the flip-chip type structure shown in FIG. 2b. In this case, the lower surface of the sapphire substrate 31, provided with the insulating light-scattering layer 37, becomes a light emitting surface. To achieve the flip-chip type nitride-based semiconductor light emitting device 40 as shown in FIG. 2b, first, the nitride-based semiconductor light emitting device 30 shown in FIG. 2a is mounted on a package substrate 41 having first and second conductor lines 42a and 42b, and then the electrodes 39a and 39b of the device 30 are connected to the first and second conductor lines 42a and 42b, respectively, by means of connecting means S, such as solder.

Referring to FIG. 2b, light coming from the active layer 35 proceeds to the light emitting surface as it is reflected at the bottom of the device 40 as designated by the arrow b, or directly proceeds to the light emitting surface as designated by the arrow a. Then, the light, arriving at the light emitting surface, is partially scattered at the light-scattering layer 37 or is effectively emitted to the outside due to a large critical angle provided by the finely roughened pattern.

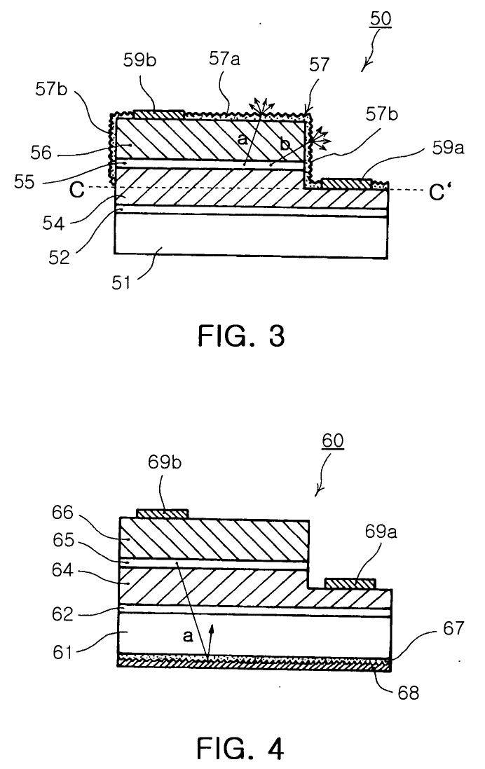

FIG. 3 is a side sectional view of a nitride-based semiconductor light emitting device in accordance with a second exemplary embodiment of the present invention.

Referring to FIG. 3, the nitride-based semiconductor light emitting device 50, in accordance with the second exemplary embodiment of the present invention, comprises a first conductivity type nitride semiconductor layer 54, an active layer 55 and a second conductivity type nitride semiconductor layer 56, which are sequentially formed on a sapphire substrate 51, provided with a buffer layer 52, in this order. The nitride-based semiconductor light emitting device 50 further comprises first and second electrodes 59a and 59b connected to the first and second conductivity type nitride semiconductor layers 54 and 56, respectively.

In the present exemplary embodiment, an insulating light-scattering layer 57 is formed at an upper surface of the nitride-based semiconductor light emitting device 50 opposite to the sapphire substrate 51 to cover part of a sidewall of the device 50 located above the line C-C′ shown in FIG. 3. The sidewall portion of the device 50, covered with the insulating light-scattering layer 57, is a region that will be exposed to the outside after mesa etching of a wafer-level process in order to allow an insulating material to be deposited thereon without any change of a conventional process. However, it is also possible to form the insulating light-scattering layer 57 over a wider sidewall region via a process change.

In the same manner as explained in relation with FIGS. 2a and 2b, the insulating light-scattering layer 57 is made of any one of light-permeable insulating materials, but is preferably made of a material having a refraction index lower than that of the first and second conductivity type nitride semiconductor layers 54 and 56. Since these GaN layers have a refraction index of 2.74, the constituent material of the insulating light-scattering layer 57 is selectable from a wider range as compared to the case that the light-scattering layer is formed on the sapphire substrate.

In the present exemplary embodiment, the upper surface of the nitride-based semiconductor light emitting device 50 becomes a light emitting surface. Thereby, light coming from the active layer 55 is scattered at an insulating light-scattering layer 57a formed at the upper surface of the device 50 as designated by the arrow a, and is also scattered at an insulating light-scattering layer 57b formed at the sidewall of the device 50 as designated by the arrow b, resulting in an improvement of light extraction efficiency.

FIG. 4 is a side sectional view of a nitride-based semiconductor light emitting device in accordance with a third exemplary embodiment of the present invention.

Referring to FIG. 4, the nitride-based semiconductor light emitting device 60, in accordance with the third exemplary embodiment of the present invention, comprises a first conductivity type nitride semiconductor layer 64, an active layer 65 and a second conductivity type nitride semiconductor layer 66, which are sequentially formed on a sapphire substrate 61, provided with a buffer layer 62, in this order. The nitride-based semiconductor light emitting device 60 further comprises first and second electrodes 69a and 69b connected to the first and second conductivity type nitride semiconductor layers 64 and 66, respectively.

In the present exemplary embodiment, an insulating light-scattering layer 67 is formed at a lower surface of the sapphire substrate 61 in the same manner as FIG. 2a, and thus detailed explanation of the insulating light-scattering layer 67 will be easily understood by reading the related explanation of FIG. 2a. A difference between the present exemplary embodiment and the first exemplary embodiment is that a reflective metal layer 68 is additionally formed at a roughly patterned surface of the insulating light-scattering layer 67.

Although a reflective metal layer is conventionally formed at the lower surface of a sapphire substrate or the upper surface of a nitride-based semiconductor light emitting device opposite to a light emitting surface, the present exemplary embodiment features that the reflective metal layer 68 is formed on the insulating light-scattering layer 67.

In this case, the reflective metal layer 68 is formed on the roughly patterned surface of the insulating light-scattering layer 67, thereby achieving a wider reflection area as well as enhanced light emitting efficiency, combined with a light-scattering effect. More specifically, an increased amount of light, directed toward the lower surface of the sapphire substrate 61, reaches the surface of the reflective metal layer as designated by the arrow a under assistance of the insulating light-scattering layer 67, and then is reflected toward the upper surface of the device 60 as a light emitting surface.

Even if the light, reflected toward the light emitting surface, is reflected reverse toward the reflective metal layer 68 due to a small critical angle as it proceeds to the sapphire substrate 61 having a high refraction index, with the present exemplary embodiment, the reflective metal layer 68 is able to reflect the light upward by virtue of its sufficient reflectivity. In this way, a light scattering effect obtainable by the insulating light-scattering layer 67 is combined with the high reflectivity of the reflective metal layer 68, resulting in an improved light extraction effect.

To more enhance the light extraction effect, preferably, the reflective metal layer 68 is made of metals having a reflectivity of more than 90%. The reflective metal layer 68 is made of at least one metal selected from among the group consisting of Ag, Al, Rh, Ru, Pt, Au, Cu, Pd, Cr, Ni, Co, Ti, In and Mo, or alloys thereof, and is preferably made of Ag, Al or alloys thereof having a high reflectivity.

Although the present exemplary embodiment suggests to form the reflective metal layer 68 on the insulating light-scattering layer 67, a formation position of the reflective metal layer 68 is not limited thereto. That is, the reflective metal layer is able to be formed on at least one surface of the light emitting device without being restricted onto a light emitting surface, and thus may be formed at an opposite side of the insulating light-scattering layer.

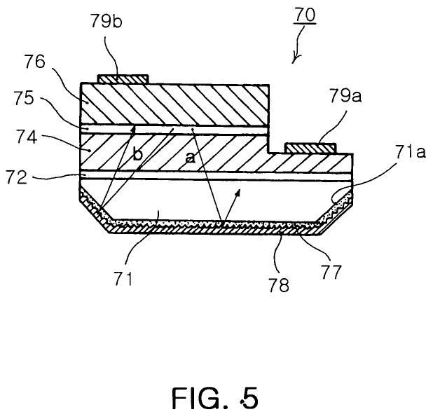

FIG. 5 is a side sectional view of a nitride-based semiconductor light emitting device in accordance with a fourth exemplary embodiment of the present invention.

Referring to FIG. 5, the nitride-based semiconductor light emitting device 70, in accordance with the fourth exemplary embodiment of the present invention, comprises a first conductivity type nitride semiconductor layer 74, an active layer 75 and a second conductivity type nitride semiconductor layer 76, which are sequentially formed on a sapphire substrate 71, provided with a buffer layer 72, in this order. The nitride-based semiconductor light emitting device 70 further comprises first and second electrodes 79a and 79b connected to the first and second conductivity type nitride semiconductor layers 74 and 76, respectively.

In the present exemplary embodiment, the sapphire substrate 71 has inclined surfaces 71a along at least a part of lateral ends of a lower surface thereof, and an insulating light-scattering layer 77 is formed to cover the lower surface of the sapphire substrate 71 and the inclined surfaces 71a. Further, a reflective metal layer 78 is formed at a roughly patterned surface of the insulating light-scattering layer 77. The sapphire substrate 71 of the present exemplary embodiment generally takes the form of a concave lens, which is effective not only to increase light extraction efficiency toward an upper surface of the device 70, but also to achieve a light focusing effect, that is difficult to achieve from the structure as shown in FIG. 4. Referring to FIG. 5, light, directed toward the lower surface of the sapphire substrate 71, is reflected upward as designed by the arrow a, in the same manner as that of FIG. 4, but light, directed toward the inclined surfaces 71a, tends to proceed to the center of an upper surface of the device 70 as designated by the arrow b. In this way, the present exemplary embodiment has the effect of raising a brightness in a desired region through an improvement of a light focusing degree.

The above described exemplary embodiments of the present invention utilize sapphire substrates mainly used for the growth of nitride, but are not limited thereto, and insulating light-scattering layers of the present invention are applicable to any other light-permeable substrates. For example, heterogeneous substrates, such as SiC or silicon substrates, and homogeneous substrates, such as InN or GaN, may be used.

Further, the exemplary embodiments of the present invention may be independently employed or may be combined with one another so long as they have the same light emitting direction as one another. For example, the reflective metal layers explained in relation with FIGS. 4 and 5 may be formed on the insulating light-scattering layer explained in relation with FIG. 3 to thereby manufacture a light emitting device applicable to a flip-chip structure.

As apparent from the above description, according to the present invention, a light-permeable insulating material is deposited on at least one surface of a light emitting device to form an insulating layer, and a roughened pattern is formed at one surface of the insulating layer, thereby achieving a light-scattering layer to improve light extraction efficiency of the light emitting device. Further, since the insulating light-scattering layer acts as a protective film, it has no harmful effect upon characteristics of the light emitting device, and can be freely formed at the overall surface of the device except for electrode formation locations. Therefore, the insulating light-scattering layer of the present invention is advantageously applicable to certain structures where the upper surface of a nitride layer serves as a light emitting surface, in addition to flip-chip structures.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A nitride-based semiconductor light emitting device comprising a first conductivity type nitride semiconductor layer, active layer and second conductivity type nitride semiconductor layer, which are sequentially formed on a light-permeable substrate in this order, further comprising:
an insulating light-scattering layer formed on at least one surface of the nitride-based semiconductor light emitting device, the light-scattering layer being made of an insulating material having a light permeability of more than 50% and being formed to have a roughened pattern for the scattering of light.

2. The device as set forth in claim 1, wherein the insulating light-scattering layer has a light permeability of more than 70%.

3. The device as set forth in claim 1, wherein the insulating light-scattering layer is made of a polymer material.

4. The device as set forth in claim 3, wherein the insulating light-scattering layer is made of epoxy resin, silicone based resin or PMMA resin.

5. The device as set forth in claim 4, wherein the insulating light-scattering layer further comprises a fluorescent material for exciting light.

6. The device as set forth in claim 1, wherein the insulating light-scattering layer is made of a material selected from the group consisting of GaN, AlN, InN, SiNx, SiC, diamond, Al₂O₃, SiO₂, SnO₂, TiO₂, ZrO₂, MgO, InOₓ and CuOₓ.

7. The device as set forth in claim 1, wherein the insulating light-scattering layer has a pattern pitch within a range of approximately 0.001 to 50 μm.

8. The device as set forth in claim 1, wherein the insulating light-scattering layer is made of a particle having a diameter of approximately 0.001 to 50 μm.

9. The device as set forth in claim 1, wherein the insulating light-scattering layer is formed on at least a lower surface of the light-permeable substrate.

10. The device as set forth in claim 9, wherein the insulating light-scattering layer is made of a material having a refraction index higher than that of the light-permeable substrate.

11. The device as set forth in claim 1, wherein the insulating light-scattering layer is formed at an upper surface of the nitride-based semiconductor light emitting device opposite to the light-permeable substrate.

12. The device as set forth in claim 11, wherein the insulating light-scattering layer extends from the upper surface of the nitride-based semiconductor light emitting device to at least a part of a sidewall of the light emitting device.

13. The device as set forth in claim 11, wherein the insulating light-scattering layer is made of a material having a refraction index higher than that of the first and second conductivity type nitride semiconductor layers.

14. The device as set forth in claim 1, further comprising:
a reflective metal layer formed on at least one surface of the nitride-based semiconductor light emitting device except for a light emitting surface.

15. The device as set forth in claim 14, wherein the reflective metal layer is formed on the insulating light-scattering layer.

16. The device as set forth in claim 14, wherein the reflective metal layer has a reflectivity of more than 90%.

17. The device as set forth in claim 14, wherein the reflective metal layer is made of at least one metal selected from the group consisting of Ag, Al, Rh, Ru, Pt, Au, Cu, Pd, Cr, Ni, Co, Ti, In and Mo or alloys thereof.

18. The device as set forth in claim 1,
wherein the light-permeable substrate has an inclined surface along at least a part of a lateral end of a lower surface thereof, and
wherein the insulating light-scattering layer is formed on at least the lower surface of the light-permeable substrate and the inclined surface.

19. The device as set forth in claim 18, wherein the insulating light-scattering layer is made of a material having a refraction index higher than the light-permeable substrate.

20. A flip-chip type nitride-based semiconductor light emitting device comprising:
a nitride-based semiconductor light emitting device having a first conductivity type nitride semiconductor layer, active layer and second conductivity type nitride semiconductor layer, which are sequentially formed on a light-permeable substrate in this order, and first and second electrodes connected to the first and second conductivity type nitride semiconductor layers, respectively;
a package substrate having first and second conductor lines to be connected to the first and second electrodes, respectively; and
an insulating light-scattering layer formed on at least a lower surface of the light-permeable substrate, the insulating light-scattering layer being made of an insulating material having a light permeability of more than 50% and being formed with a roughened pattern for the scattering of light.

21. The device as set forth in claim 20, wherein the insulating light-scattering layer is made of a material having a refraction index higher than that of the light-permeable substrate.

22. The device as set forth in claim 20, wherein the insulating light-scattering layer is made of a polymer material.

23. The device as set forth in claim 22, wherein the insulating light-scattering layer is made of epoxy resin, silicone based resin or PMMA resin.

24. The device as set forth in claim 23, wherein the insulating light-scattering layer further comprises a fluorescent material for exciting light.

25. The device as set forth in claim 20, wherein the insulating light-scattering layer is made of a material selected from the group consisting of GaN, AlN, InN, SiNx, SiC, diamond, Al₂O₃, SiO₂, SnO₂, TiO₂, ZrO₂, MgO, InOₓ and CuOₓ.

26. The device as set forth in claim 20, wherein the insulating light-scattering layer has a pattern pitch within a range of approximately 0.001 to 50 μm.

27. The device as set forth in claim 20, wherein the insulating light-scattering layer is made of a particle having a diameter of approximately 0.001 to 50 μm.
